(19) United States
(12) Patent Application Publication
(10) Pub. No.: US 2018/0330651 A1
(43) Pub. Date: Nov. 15, 2018

(54) INSPECTION APPARATUS

(71) Applicant: Sakai Display Products Corporation, Osaka (JP)

(72) Inventors: Akiyoshi MIYATANI, Osaka (JP); Nobuhiro YONEZAWA, Osaka (JP)

(21) Appl. No.: 16/045,362

(22) Filed: Jul. 25, 2018

Related U.S. Application Data
(63) Continuation-in-part of application No. PCT/JP2016/053705, filed on Feb. 8, 2016.

(51) Int. Cl. G09G 3/00; G01R 1/04; G06F 1/16; H05K 1/02; H05K 1/14

(52) U.S. Cl. CPC G09G 3/006; G01R 1/0408; H05K 1/147; H05K 1/028; G06F 1/1652

(57) ABSTRACT

The inspection apparatus (100) according to the present invention includes a holding part (40) for sandwiching and holding the display panel (50) from both surfaces of the display panel (50), the holding part (40) having flexibility, a pair of retaining parts (21, 22) for retaining both ends of the holding part (40), the pair of retaining parts (21, 22) being separated from each other, and an adjustment part (60) configured to adjust a distance between the pair of retaining parts (21, 22) in a separation direction so as to set the holding part (40) to have a desired degree of curvature.

### CROSS-REFERENCE TO RELATED APPLICATION

This is a continuation-in-part of PCT international application No. PCT/JP2016/053705 filed on Feb. 8, 2016, incorporated herein by reference.

### BACKGROUND OF THE INVENTION

The present invention relates to an inspection apparatus for inspecting a flexible display panel by causing the display panel to deform into a curved shape.

### BACKGROUND ART

Recent liquid crystal displays (LCDs) are representative flat panel displays widely used not only in the field of small and medium panels but also in the field of large image display panels for TVs. If such display panels having large screens can be attached not only to planer walls but also to curved walls, the possibility of installing the display panels at a wide variety of places will increase. As a merit of deforming a display panel into a curved shape, the realistic sensation or visibility can be improved. Accordingly, there are increasing demands for display panels whose display surfaces can be curved.

In a case where a planar display panel is curved and then assembled in a frame or the like, if inspection of the display panel reveals any failure of the display panel, an additional work for removing the failed display panel after gradually releasing elastic deformation of the curved display panel is required. As a result, the work efficiency is lowered.

JP H10-260424 A discloses an inspection apparatus capable of performing inspection by mounting a display panel on a mounting part having a mounting surface similar to a curved surface of the display panel and subsequently pushing a handle part down to cause a rotary part to rotate toward the mounting part to deform the display panel into a curved shape.

### SUMMARY OF THE INVENTION

According to the inspection apparatus disclosed in JP H10-260424 A, since the curved display panel is kept in an elastically deformed state during the inspection, pushing up the handle part after completing the inspection may unintentionally damage the display panel due to spring-back of the elastically deformed display panel. In addition, since the mounting surface is a curved surface having a specific curvature, the inspection can be performed only when an inspection target display panel is in a curved state of the same curvature.

The present invention has been made in view of the circumstance described above, and an object of the present invention is to provide an inspection apparatus capable of preventing a display panel from being damaged due to spring-back.

An inspection apparatus according to an embodiment of the present invention is an inspection apparatus for inspecting a display panel having flexibility by causing the display panel to deform into a curved shape, and includes a holding part for sandwiching and holding the display panel from both surfaces of the display panel wherein the holding part having flexibility, a pair of retaining parts for retaining both ends of the holding part wherein the pair of retaining parts being separated from each other, and an adjustment part configured to adjust a first distance between the pair of retaining parts in a separation direction so as to set the holding part to have a desired degree of curvature.

The present invention can prevent the display panel from being damaged due to spring-back.

### BRIEF DESCRIPTION OF THE DRAWINGS

FIG. 1 is a plan view illustrating an exemplary configuration of an inspection apparatus according to an embodiment.

FIG. 2 is a front view illustrating an exemplary configuration of the inspection apparatus according to the embodiment.

FIG. 3 is a plan view illustrating an exemplary state of the inspection apparatus according to the embodiment, in which a holding part is curved.

FIG. 4 is a front view illustrating an exemplary operational state of light sources of the inspection apparatus according to the embodiment.

FIG. 5 is a front view illustrating an exemplary curved state of the holding part of the inspection apparatus according to the embodiment.

FIG. 6 is a front view illustrating an essential part of a conventional inspection apparatus using a planar backlight.

### DETAILED DESCRIPTION

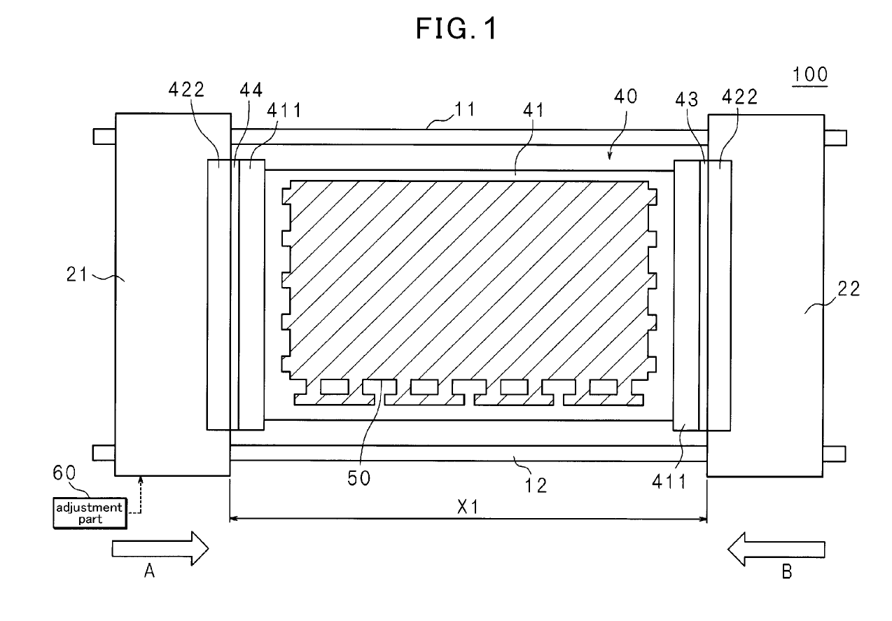

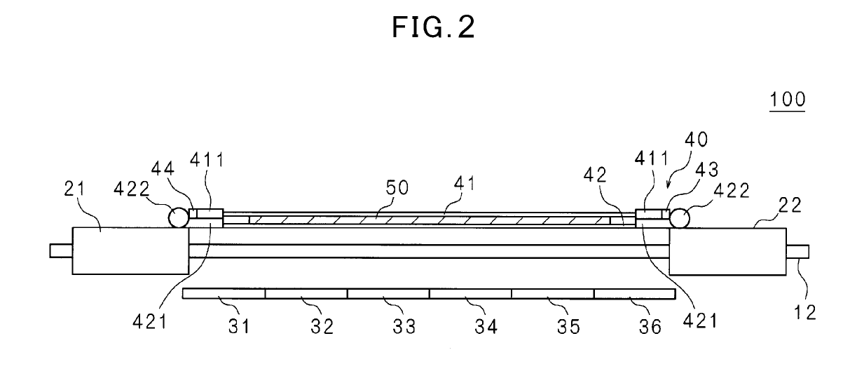

Hereinafter, embodiments of the present invention will be described with reference to attached drawings illustrating exemplary embodiments. FIG. 1 is a plan view illustrating an exemplary configuration of an inspection apparatus 100 according to an embodiment. FIG. 2 is a front view illustrating an exemplary configuration of the inspection apparatus 100 according to the embodiment. The inspection apparatus 100 according to the embodiment includes elongated rails 11 and 12, a holding part 40, a pair of retaining parts 21 and 22, and an adjustment part 60. The inspection apparatus 100 is an apparatus for inspecting a display panel 50 having flexibility by causing the display panel 50 to deform into a curved shape.

The display panel 50 is a so-called open cell state panel including a glass substrate, color filters, liquid crystals, polarizing filters, alignment films, transparent electrodes, liquid crystal drivers, and spacers, in a state where a backlight, a bezel, and other components are not yet mounted. The display panel 50 is rectangular in a plan view and has predetermined dimensions vertically and horizontally. In the following description, for the sake of convenience, the direction along long sides of the rectangular display panel 50 is referred to as horizontal direction and the direction along short sides of the rectangular display panel 50 is referred to as vertical direction. However, this description does not intend to exclude a square display panel.

The rails 11 and 12 are separated and disposed to oppose with each other to have an interval longer than the vertical dimension of the display panel 50. More specifically, the rails 11 and 12 are disposed in parallel with the horizontal direction of the display panel 50. The rails 11 and 12 are fixed to a base (not illustrated) for supporting the rails 11 and 12.

The pair of retaining parts 21, 22 are configured to retain both ends of the holding part 40. In the embodiment, the pair of retaining parts 21 and 22, which is hereinafter referred to as a first retaining part 21 and a second retaining part 22, are mounted to the rails 11 and 12 so as to be movable in the longitudinal direction of the rails 11 and 12 (the horizontal direction of the display panel 50). The first retaining part 21 and the second retaining part 22 are separated from each other in the longitudinal direction of the rails 11 and 12 (separation direction). In the embodiment, both of the first and second retaining parts 21 and 22 are configured to be movable in the longitudinal direction of the rails 11 and 12. However, as an alternative, one of the first and second retaining parts 21 and 22 can be fixed to the rails 11 and 12 and the other is configured to be movable. In the embodiment, the rails 11 and 12 are shown as one example of transfer mechanism for guiding at least one of the first retaining part 21 and the second retaining part 22 along the separation direction. However, the transfer mechanism is not limited to the rails 11 and 12. For example, the transfer mechanism may be a guide groove, guide slot or other guide part/member provided to a base (not illustrated), which can guide at least one of the first retaining part 21 and the second retaining part 22.

The holding part 40 has flexibility, and is transparent in the embodiment. The holding part 40 is larger than the display panel 50 in both of the vertical and horizontal directions and is configured to sandwich and hold the display panel 50 from both surfaces of the display panel 50. The holding part 40 has a first end held by the first retaining part 21 and a second end held by the second retaining part 22.

As illustrated in FIGS. 1 and 2, the holding part 40 has a bottom plate 42 for mounting the display panel 50 and a top plate 41 capable of pressing the display panel 50 toward the bottom plate 42. The bottom plate 42 has a rectangular shape larger than the display panel 50 in both of the vertical and horizontal directions. The top plate 41 has a shape and size comparable to the bottom plate 42. Each of the top plate 41 and the bottom plate 42 has flexibility and made of a transparent synthetic resin. For example, the top plate 41 and the bottom plate 42 are acrylic plates, although they are not limited to the acrylic plates.

The holding part 40 includes a pair of first supporting parts 411 supporting both ends of the top plate 41 and a pair of second supporting parts 421 supporting both ends of the bottom plate 42. Each of the pair of second supporting parts 421 has a rectangular shape in a plan view and fixed to corresponding ends of the bottom plate 42. One of the pair of second supporting parts 421 has a hinge 422 fixed to the first retaining part 21. The other of the pair of second supporting parts 421 has a hinge 422 fixed to the second retaining part 22. The hinges 422 are configured to enable the second supporting parts 421 to rotate around an axis parallel to the vertical direction of the display panel 50 with respect to the first/second retaining part 21, 22. In addition, although not illustrated, the bottom plate 42 has a positioning part for positioning the display panel 50 at a predetermined position when the display panel 50 is placed on the bottom plate 42.

Each of the pair of first supporting parts 411 has a rectangular shape in a plan view and fixed to corresponding ends of the top plate 41. The first supporting part 411 and the second supporting part 421, which are provided adjacent to the first retaining part 21, are fixed with each other by a fixing member 44. In addition, the first supporting part 411 and the second supporting part 421, which are provided adjacent to the second retaining part 22, are fixed with each other by a fixing member 43. Fixing and locking the first supporting parts 411 and the second supporting parts 421 with each other by the fixing members 43 and 44 in the thickness direction of the display panel 50 can cause the top plate 41 to press the display panel 50 toward the bottom plate 42. As a result, the display panel 50 can be surely sandwiched and held between the top plate 41 and the bottom plate 42.

The fixing members 43 and 44 can be configured to have any structure and are not limited to specific members, as long as the first supporting parts 411 and the second supporting parts 421 can be fixed at both ends. For example, the fixing members 43 and 44 can be configured to have a fitting structure or a screw fixing structure. In addition, one of the first supporting part 411 and the second supporting part 421 can be configured to have a hinge structure and the top plate 41 can be configured to be rotatable around the axis parallel to the vertical direction of the display panel 50 at one end thereof, so that the top plate 41 is openable with respect to the bottom plate 42.

The inspection apparatus 100 includes a plurality of light sources 31, 32, 33, 34, 35, and 36, each of which is disposed so as to face the bottom plate 42. The plurality of light sources 31 to 36 are disposed in the horizontal direction of the display panel 50 (separation direction between the first retaining part 21 and the second retaining part 22) to emit light toward the bottom plate 42 (the holding part 40). The light sources 31 to 36 cooperatively constitute a surface light source functioning as a backlight, and are separated and independent from each other.

For example, the adjustment part 60 has a driving mechanism (not illustrated), which can move at least one of the first and second retaining parts 21 and 22 (in the embodiment, first and second retaining parts 21 and 22 are moved) along the rails 11 and 12.

More specifically, the adjustment part 60 can adjust a distance X (first distance) between the first retaining part 21 and the second retaining part 22 in the separation direction (the horizontal direction of the display panel 50). As illustrated in FIGS. 1 and 2, the holding part 40 (the top plate 41 and the bottom plate 42) has a planar shape when the distance X between the first retaining part 21 and the second retaining part 22 in the separation direction is adjusted to a predetermined value X1 by the adjustment part 60.

Hereinafter, an exemplary method for inspecting the display panel 50, by the inspection apparatus 100 according to the embodiment, will be described. The holding part 40 is configured that the display panel 50 is attachable to and detachable from the holding part 40 when the distance X between the first retaining part 21 and the second retaining part 22 in the separation direction is adjusted to the predetermined value X1 by the adjustment part 60.

For example, the holding part 40 is a planar shape when the adjustment part 60 adjusts the distance X to the predetermined value X1. In this state, when the fixing members 43 and 44 are released from their locked states, the display panel 50 can be mounted to the holding part 40 in a state where the display panel 50 is planar. More specifically, sandwiching the display panel 50 between the top plate 41 and the bottom plate 42 after placing the display panel 50 on the bottom plate 42 and then mutually fixing and locking the first supporting parts 411 and the second supporting parts 421 at both ends of the holding part 40 with the fixing members 43 and 44 can complete the mounting of the display panel 50 onto the holding part 40.

In addition, a connector of a driving signal supply unit (not illustrated) may be connected to a predetermined electrode of the display panel 50 for inspection. After the connector is connected to the electrode of the display panel 50, a predetermined driving signal is supplied from the driving signal supply unit to the display panel 50 to inspect the display panel 50.

In the embodiment, the adjustment part 60 moves the first retaining part 21 at a predetermined speed in a direction indicated by arrow A in FIG. 1 and moves the second retaining part 22 at a predetermined speed in a direction indicated by arrow B in FIG. 1. As a result, the holding part 40 and the display panel 50 are gradually curved as the distance X between the first retaining part 21 and the second retaining part 22 in the separation direction becomes shorter. The adjustment part 60 can set the holding part 40 (namely, the display panel 50) to have a predetermined degree of curvature by adjusting the distance X between the first retaining part 21 and the second retaining part 22 in the separation direction.

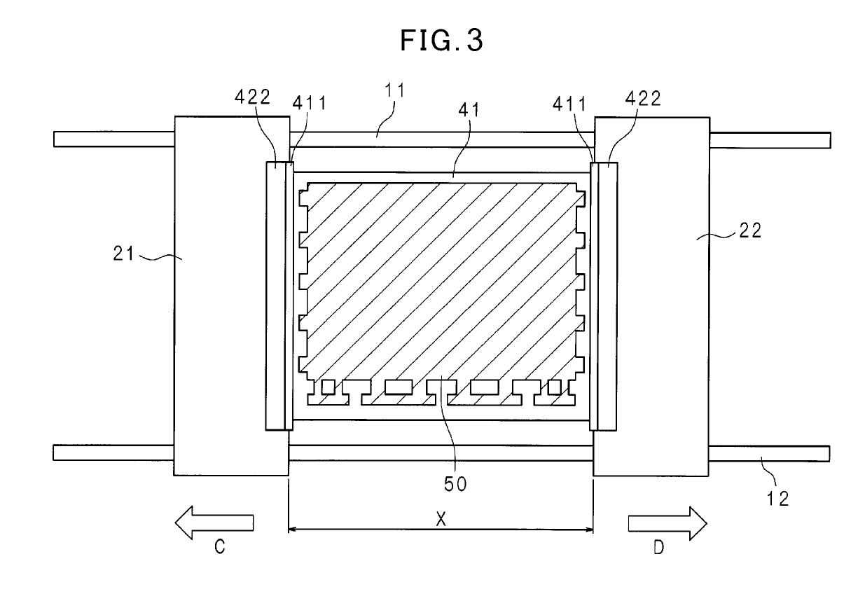

FIG. 3 is a plan view illustrating an exemplary state of the inspection apparatus 100 according to the embodiment, in which the holding part 40 is curved. The display panel 50 can be inspected by supplying the predetermined driving signal to the display panel 50 in the state where the display panel 50 is curved as illustrated in FIG. 3.

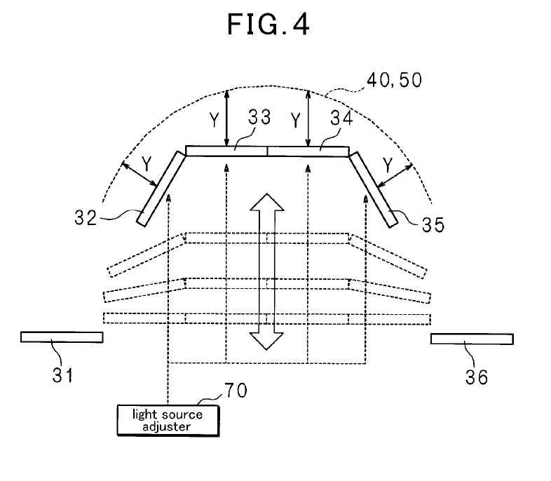

FIG. 4 is a front view illustrating an exemplary operational state of the light sources 31 to 36 of the inspection apparatus 100 according to the embodiment. In the embodiment, the inspection apparatus 100 has a light source adjuster 70. The light source adjuster 70 has a driving mechanism (not illustrated) for moving a part of or all of the light sources 31 to 36 individually. In the embodiment, the light source adjuster 70 moves the light sources 32 to 35 individually. The light source adjuster 70 is configured to adjust a distance Y (second distance) between each of the light sources 31 to 36 and the holding part 40 (namely, the display panel 50) depending on the distance X (first distance) adjusted by the adjustment part 60. In the embodiment, distance Y is the distance from the light-emitting surface of each of the light sources 31 to 36 to the surface of holding part 40 in a direction orthogonal to the light-emitting surface of each of the light sources 31 to 36.

According to the example illustrated in FIG. 4, as the distance X between the first retaining part 21 and the second retaining part 22 in the separation direction becomes shorter by the adjustment part 60, the light source adjuster 70 pushes up the light sources 33 and 34, which are positioned in a central region in the separation direction, toward the display panel 50 so that the light sources 33 and 34 come close to the display panel 50. In addition, in order to direct the light emitted from the light sources 32 and 35, which are provided adjacent to the light sources 33 and 34, toward the display panel 50, the light source adjuster 70 inclines the light sources 32 and 35 so that light-emitting surfaces of the light sources 32 and 35 become substantially parallel to a light incident surface of the display panel 50. The light sources 31 and 36 remain fixedly at the original positions.

The above-mentioned adjustments with respect to the light-emitting direction of respective light sources 31 to 36 and the distance between the light sources 31 to 36 and the display panel 50 are mere examples. The present invention is not limited to the exemplary configuration illustrated in FIG. 4. In addition, the number of the light sources 31 to 36 is not limited to the example illustrated in FIG. 4. More specifically, as long as the entire surface of the curved display panel 50 can be uniformly irradiated with light, the light sources can be arbitrarily arranged and appropriately adjusted.

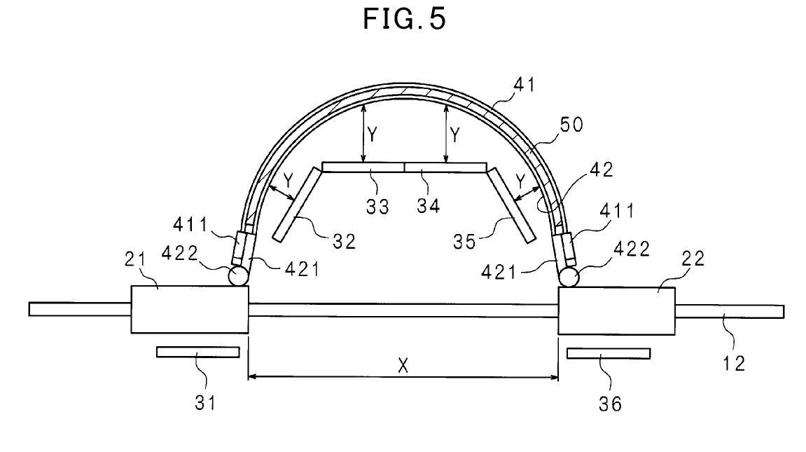

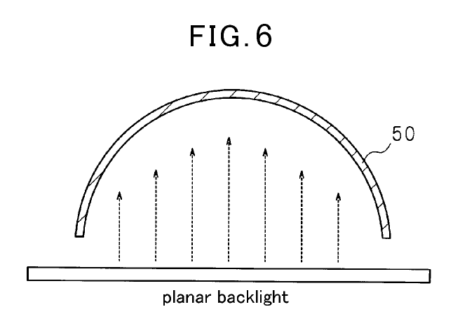

FIG. 5 is a front view illustrating an exemplary curved state of the holding part 40 of the inspection apparatus 100 according to the embodiment. FIG. 6 is a front view illustrating an essential part of a conventional inspection apparatus using a planar backlight. As illustrated in FIG. 6, according to the conventional inspection apparatus, in a process of curving the display panel 50 from a flat state, each portion of the display panel 50 moves away from the planar backlight in the direction orthogonal to the separation direction. The distance from the planar backlight to each portion of the display panel 50 (hereinafter displacement amount) varies along the separation direction. A displacement amount in the central region of the display panel 50 is larger compared to a displacement amount in an end region of the display panel 50. Therefore, in the case where the planar backlight for emitting light to the display panel 50 is fixed in position and does not move as illustrated in FIG. 6, the distance between the planar backlight and the display panel 50 in the central region of the display panel 50 is relatively longer and the distance between the planar backlight and the display panel 50 in the end region of the display panel 50 is relatively shorter. Therefore, inspecting the display panel 50 with uniform luminance is unfeasible.

On the other hand, in the inspection apparatus 100 according to the embodiment, as illustrated in FIG. 5, the light source adjuster 70 adjusts the distance Y between respective light sources 31 to 36 and the holding part 40 (the display panel 50) and the inclination of respective light sources 31 to 36 depending on the distance X adjusted by the adjustment part 60. Accordingly, for example, a moving distance of the light source corresponding to a central region of the holding part 40 (the display panel 50) in the direction orthogonal to the separation direction can be set to be greater than a moving distance of the light source corresponding to an end region of the holding part 40 (the display panel 50) in the direction orthogonal to the separation direction. Therefore, distance between the light source and the display panel 50 along the separation direction (in both the central region and the end region) can be equivalent or the difference in distance between the light source and the display panel 50 along the separation direction can be shortened. Therefore, inspecting the display panel 50 with uniform luminance is feasible.

Upon completing the inspection of the display panel 50, the adjustment part 60 moves the first retaining part 21 in a direction indicated by arrow C illustrated in FIG. 3 and moves the second retaining part 22 in a direction indicated by arrow D illustrated in FIG. 3. Thus, the inspection apparatus 100 returns to the state illustrated in FIGS. 1 and 2. The display panel 50 can be returned to a planar shape correspondingly, while releasing the elastic deformation of the display panel 50.

The inspection apparatus 100 according to the embodiment includes the holding part 40 for sandwiching and holding the display panel 50 from both surfaces of the display panel 50 wherein the holding part 40 has flexibility, the pair of retaining parts 21 and 22 for retaining both ends of the holding part 40 wherein the pair of retaining parts 21 and 22 being separated from each other, and the adjustment part 60 configured to adjust a distance X between the pair of retaining parts 21 and 22 in the separation direction so as to set the holding part 40 to have a desired degree of curvature. When the distance X between the pair of retaining parts 21 and 22 is adjusted to the predetermined value X1 (the exemplary states illustrated in FIGS. 1 and 2) by the adjustment part 60, the display panel 50 can be removed from the holding part 40 in a state where the display panel 50 is flat. Accordingly, releasing the elastic deformation of the display panel 50 is feasible, and the elastically deformed display panel 50 can be prevented from being damaged due to spring-back.

In addition, the inspection apparatus 100 according to the embodiment includes the transfer mechanism for guiding at least one of the pair of retaining parts 21 and 22 along the separation direction. More specifically, the inspection apparatus 100 includes the elongated rails 11 and 12 as the transfer mechanism disposed in parallel with the separation direction. The adjustment part 60 moves the at least one of the pair of retaining parts 21 and 22 and adjusts the distance X by using the transfer mechanism. More specifically, the adjustment part 60 moves at least one of the pair of retaining parts 21 and 22 along the rails 11 and 12 and adjusts the distance X between the pair of retaining parts 21 and 22 in the separation direction. For example, when the distance X is set to be relatively longer (although X<X1), the degree of curvature of the holding part 40 (more specifically, the display panel 50) can be reduced. In addition, when the distance X is set to be relatively shorter (although X<X1), the degree of curvature of the holding part 40 (more specifically, the display panel 50) can be increased. Moving at least one of the pair of retaining parts 21 and 22 along the rails 11 and 12 can bring the holding part 40 (more specifically, the display panel 50) into a desired curved state. Therefore, the display panel 50 can be inspected in a state where the display panel 50 is curved to have a desired curvature.

In the inspection apparatus 100 according to the embodiment, the holding part 40 has a planar shape when the distance X between the pair of retaining parts 21 and 22 in the separation direction is adjusted to the predetermined value X1 by the adjustment part 60. Since adjusting the distance X to the predetermined value X1 flattens the holding part 40, the display panel 50 can be returned to the original planar shape from its curved shape and the elastically deformed state can be released.

In the inspection apparatus 100 according to the embodiment, the holding part 40 is configured that the display panel 50 is attachable to and detachable from the holding part 40 when the distance X between the pair of retaining parts 21 and 22 in the separation direction is adjusted to the predetermined value X1 by the adjustment part 60. For example, setting the holding part 40 to have a planar shape when the adjustment part 60 has adjusted the distance X to the predetermined value X1 can realize attachment and detachment of the display panel 50 in the planar state and can prevent the elastically deformed display panel 50 from being damaged due to spring-back when the display panel 50 is attached to or detached from the holding part 40.

In the inspection apparatus 100 according to the embodiment, the holding part 40 includes the bottom plate 42 having a rectangular shape to mount the display panel 50 and the top plate 41 for pressing the display panel 50 toward the bottom plate 42 and the top plate 41 has a rectangular shape. The top plate 41 is openable with respect to the bottom plate 42 when the distance X between the pair of retaining parts 21 and 22 in the separation direction is adjusted to the predetermined value X1 by the adjustment part 60. For example, setting the holding part 40 to have a planar shape when the adjustment part 60 has adjusted the distance X to the predetermined value X1 can prevent the elastically deformed display panel 50 from being damaged due to spring-back when the top plate 41 is opened, because the top plate 41 can be opened in the state where the display panel 50 has a planar shape.

The inspection apparatus 100 according to the embodiment includes the plurality of light sources 31 to 36 disposed along the separation direction to emit light toward the holding part 40, and the light source adjuster 70 configured to adjust the distance Y between each of the light sources 31 to 36 and the holding part 40 depending on the distance X adjusted by the adjustment part 60. In such a configuration, the distance between the light source and the display panel 50 along the separation direction (in both the central region and the end region) can be equivalent or the difference in distance between the light source and the display panel 50 along the separation direction can be shortened even when the display panel 50 is curved to have an arbitrary curvature. Therefore, inspecting the display panel 50 with uniform luminance is feasible.

The embodiment is not limited for the inspection of liquid crystal display panels. The inspection apparatus according to the embodiment can be applied to any display panel having a structure elastically deformable when mounted on a display device.

In the embodiment, although the inspection apparatus 100 includes two rails 11 and 12, the inspection apparatus 100 can be modified to include only one rail or three rails.

In addition, in the embodiment, the inspection apparatus 100 includes the rails 11 and 12 as a transfer mechanism and the adjustment part 60 adjusts the distance X by moving at least one of the pair of retaining parts 21 and 22 along the rails 11 and 12. However, the present invention is not limited to the illustrated example. For example, the inspection apparatus 100 may be configured to include ball screws or air cylinders as a transfer mechanism comparable to the rails 11 and 12. In this case, the adjustment part 60 can adjust the distance X by using the transfer mechanism (e.g., the ball screws or the air cylinders) to move at least one of the pair of retaining parts 21 and 22 in the separation direction.

The configurations described in the above-mentioned embodiments are mutually combinable. Appropriately combining the above-mentioned configurations can derive new technical features.

What is claimed is:

1. An inspection apparatus for inspecting a display panel having flexibility by causing the display panel to deform into a curved shape, comprising:
a holding part for sandwiching and holding the display panel from both surfaces of the display panel, the holding part having flexibility;
a pair of retaining parts for retaining both ends of the holding part, the pair of retaining parts being separated from each other; and
an adjustment part configured to adjust a first distance between the pair of retaining parts in a separation direction so as to set the holding part to have a desired degree of curvature.

2. The inspection apparatus according to claim 1, further comprising a transfer mechanism for guiding at least one of the pair of retaining parts along the separation direction,
wherein the adjustment part moves the at least one of the pair of retaining parts and adjusts the first distance by using the transfer mechanism.

3. The inspection apparatus according to claim 2, wherein the transfer mechanism includes elongated rails disposed in parallel with the separation direction, and the adjustment part moves at least one of the pair of retaining parts along the rails and adjusts the first distance between the pair of retaining parts in the separation direction.

4. The inspection apparatus according to claim 1, wherein the holding part has a planar shape when the first distance between the pair of retaining parts in the separation direction is adjusted to a predetermined value by the adjustment part.

5. The inspection apparatus according to claim 4, wherein the holding part is configured that the display panel is attachable to and detachable from the holding part when the first distance between the pair of retaining parts in the separation direction is adjusted to the predetermined value by the adjustment part.

6. The inspection apparatus according to claim 4, wherein the holding part includes
a bottom plate having a rectangular shape to mount the display panel, and
a top plate for pressing the display panel toward the bottom plate, the top plate having a rectangular shape,
wherein the top plate is openable with respect to the bottom plate when the first distance between the pair of retaining parts in the separation direction is adjusted to the predetermined value by the adjustment part.

7. The inspection apparatus according to claim 1, further comprising:
a plurality of light sources disposed along the separation direction to emit light toward the holding part, and
a light source adjuster configured to adjust a second distance between each of the light sources and the holding part depending on the first distance adjusted by the adjustment part.
